(19) United States
(12) Patent Application Publication
(10) Pub. No.: US 2020/0144468 A1
(43) Pub. Date: May 7, 2020

(54) SYSTEMS INCLUDING AN LED AND A LIGHT GUIDE

(71) Applicant: LiliBrand LLC, Brooklyn, NY (US)

(72) Inventor: Noam Meir, Herzliya (IL)

(73) Assignee: LiliBrand LLC, Brooklyn, NY (US)

(21) Appl. No.: 16/509,200

(22) Filed: Jul. 11, 2019

Related U.S. Application Data
(60) Provisional application No. 62/723,298, filed on Aug. 27, 2018.
(60) Provisional application No. 62/696,705, filed on Jul. 11, 2018.

(51) Int. Cl. H01L 33/60; F21K 9/61

(52) U.S. Cl. CPC H01L 33/60; F21K 9/61

(57) ABSTRACT

Systems that include an LED and a light guide designed to receive light emitted by the LED.

### CROSS-REFERENCE TO RELATED APPLICATIONS

This application claims priority to each of U.S. Provisional Application Ser. No. 62/696,705, titled “Integrated Silicone Structure” filed on Jul. 11, 2018 and U.S. Provisional Application Ser. No. 62/723,298, titled “Light Pipe” filed on Aug. 27, 2018, both of which are incorporated herein by reference in their entireties.

### FIELD

The invention relates generally to lighting and illumination systems, and more particularly, to lighting and illumination systems that include a light-emitting diode (i.e., LED) and a light guide (e.g., light pipe) that receives light emitted by the LED.

### BACKGROUND

Light emitting diodes (LEDs) are typically formed from a semiconductor material that is doped to create a p-n junction. The LEDs typically emit light in a narrow spectrum (e.g., a spectrum that is smaller 100 nanometers in size) that is dependent upon the bandgap energy of the semiconductor material that forms the p-n junction.

In some application, lighting and illumination systems may include one or more optical component that receives light emitted from an LED. For example, a light guide is a type of optical component that may be used to receive light emitted from an LED and transmit the light to a different location. For example, light may propagate through the light guide to an exit aperture where it is emitted from the light guide.

### SUMMARY

Systems that include an LED and a light guide designed to receive light emitted by the LED are described herein.

In some aspects, a system is provided. The system may comprise a light-emitting diode and a light guide configured to receive light emitted by the light-emitting diode. The light propagates inside the light guide. The light guide can comprise at least one hole that extends from a top surface of the light guide to a bottom surface of the light guide. The hole may be defined by an inner surface which may be coated with a reflective material.

In some embodiments, the light guide can comprise a plurality of holes that extend from a top surface of the light guide to a bottom surface of the light guide. The holes may be respectively defined by inner surfaces. The inner surfaces may be coated with a reflective material.

In some embodiments, the reflective material may have a reflectivity of at least 92%. The inner surface(s) may be coated with a diffuse reflective material which, for example, may be a silicone material.

In some embodiments, the light that propagates inside the light guide can interact with the hole(s) and may be scattered into multiple directions and continues to propagate inside the light guide.

In some embodiments, the light-emitting diode may emit light into a side of the light guide. The light-emitting diode may emit light into a bottom of the light guide.

In some embodiments, a plurality of light-emitting diodes (e.g., an array) may emit light that is received by the light guide.

For example, the holes can have a circular cross-section and/or a cylindrical shape.

In some embodiments, the light guide may comprise a silicone material. The light guide may be a light pipe.

In some aspects, a system is provided. The system may comprise a light-emitting diode configured to emit light. The system may comprise a light guide configured to receive the light emitted by the light-emitting diode through an entrance aperture. The light can propagate inside the light guide and may be emitted through an exit aperture. The light guide may have a length that extends from the entrance aperture to the exit aperture and a width that is perpendicular to the length and defines a cross-section of the light guide. Exterior surfaces of the light guide, except for the entrance aperture and the exit aperture, may be coated with a reflective material that reflects greater than 92% of the transmitted light.

In some embodiments, the light guide may be a light pipe.

In some embodiments, the reflective material reflects greater than 95% of the transmitted light. For example, the reflective material may be opaque.

In some embodiments, the light can propagate from the entrance aperture to the exit aperture with substantially no leakage.

In some embodiments, the light guide comprises a silicone material.

In some embodiments, the light guide comprises a continuous geometric shape.

In some aspects, a system is provided. The system may comprise a light-emitting diode configured to emit light and a light guide configured to receive the light emitted by the light-emitting diode. The light may propagate inside the light guide. The light guide may be a molded structure comprising a silicone material and includes a light coupling pattern on an exterior surface of the light guide.

The light guide may include a light coupling pattern on a bottom surface of the light guide. The light guide may include a light coupling pattern on a side surface of the light guide. For example, the light guide may include an out-coupling pattern and/or an in-coupling pattern.

In some embodiments, the light-emitting diode may be embedded in the light guide. In some embodiments, the light-emitting diode may be positioned in an air cavity formed within the light guide.

In some embodiments, the light-emitting diode may emit light into a side surface of the light guide. In some embodiments, the light-emitting diode may emit light into a bottom surface of the light guide.

In some embodiments, the system can comprise a plurality of light-emitting diodes (e.g., an array) configured to emit light that is received by the light guide.

In some embodiments, the system can comprise a bottom diffuse reflector arranged proximate a bottom surface of the light guide and/or a top diffuse reflector arranged proximate a top surface of the light guide.

In some embodiments, the light-emitting diode(s) are mounted on a printed circuit board.

In some embodiments, the silicone material may be a potting material.

The light guide may comprise a portion that includes phosphor material configured to convert the wavelength of the light emitted by the light-emitting diode. In some embodiments, a white reflective layer on top of the portion.

In some embodiments, the light coupling pattern may comprise a plurality of hemispheres. In some embodiments, the light coupling pattern may comprise a plurality of prisms.

Other aspects, embodiments and features will become apparent from the following non-limiting detailed description when considered in conjunction with the accompanying drawings, which are schematic and which are not intended to be drawn to scale. In the figures, each identical or nearly identical component that is illustrated in various figures typically is represented by a single numeral. For purposes of clarity, not every component is labeled in every figure, nor is every component of each embodiment shown where illustration is not necessary to allow those of ordinary skill in the art to understand the invention. In cases where the present specification and a document incorporated by reference include conflicting disclosure, the present specification shall control.

### BRIEF DESCRIPTION OF DRAWINGS

FIG. 1 shows a schematic of a system including an array of LEDs configured to emit light into a side of a light guide according to some embodiments.

FIG. 2 shows a schematic of a system including an array of LEDs configured to emit light into a bottom of a light guide according to some embodiments.

FIG. 3 shows a schematic of a light guide that is a light pipe according to some embodiments.

FIG. 4 shows a schematic of a light guide including a hole that extends from a top surface to a bottom surface of the light guide according to some embodiments.

FIG. 5 shows the light intensity distribution on a top surface of the light guide for System 1 as described in Example 1.

FIG. 6 shows the light intensity distribution on a top surface of the light guide for System 2 as described in Example 1.

FIG. 7 shows the light intensity distribution on a top surface of the light guide for System 3 as described in Example 1.

FIG. 8 shows the light intensity distribution on a top surface of the light guide for System 4 as described in Example 1.

FIG. 9 shows a schematic of Simulated Systems 1A-1F as described in Example 2.

FIG. 10 shows a schematic of Simulated Systems 2A-2C as described in Example 2.

### DETAILED DESCRIPTION

Systems that include an LED (or a plurality of LEDs) and a light guide designed to receive light emitted by the LED(s) are described herein. The light can propagate inside the light guide from an entry location (e.g., entry aperture) to an exit location (e.g., exit aperture). In this way, light may be transmitted from the LED emission surface to a light emitting surface of the light guide which is distant from the emission surface. As described further below, the light guide may be designed to have a number features/characteristics which enhance performance and/or facilitate its manufacturing. For example, the light guide may be made of a silicone material. In some cases, exterior surfaces of the light guide may be coated, for example, with a reflective material. In some embodiments, the light guide may comprise one or more holes that extend from its top to bottom surface. The holes may include inner surfaces coated with a reflective material. The systems described herein may be used in a variety of lighting and/or illumination applications.

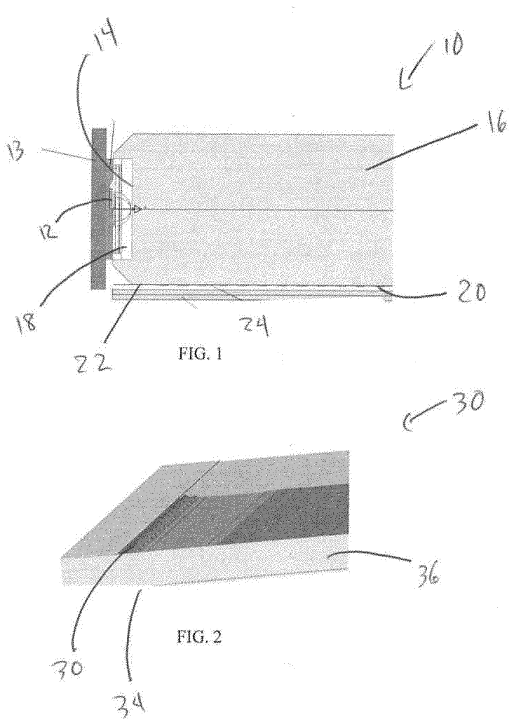

FIG. 1 illustrates a system 10 according to an embodiment. The system includes an array of LEDs 12 mounted on a printed circuit board (PCB) 13. The LEDs emit light into a side 14 of a light guide 16 (“side in-coupling”). As shown, the LEDs are positioned within an air cavity 18 of the light guide. An out-coupling structure 20 is formed on a bottom surface 22 of the light guide. The system includes a bottom diffuse reflector 24. In some embodiments, not shown, the system includes a top diffuse reflector. In some embodiments, exterior surfaces (e.g., top, bottom and/or sides) of the light guide and PCB are coated with a white diffuse reflector.

FIG. 2 illustrates a system 30 according to an embodiment. The system includes an array of LEDs 32 that emit light into a bottom surface 34 of the light guide 36. In this embodiment, the LEDs are embedded in the light guide, as described further below. The LEDs are mounted on a PCB which is also embedded, at least in part, in the light guide. In this embodiment, the LEDs emit light into a bottom surface of the light guide (“bottom in-coupling”). The system may include a bottom diffuse reflector and a top diffuse reflector. In some embodiments, a prismatic groove may be positioned above the array of LEDs. In some embodiments, exterior surfaces (e.g., top, bottom and/or sides) of the light guide and PCB are coated with a white diffuse reflector.

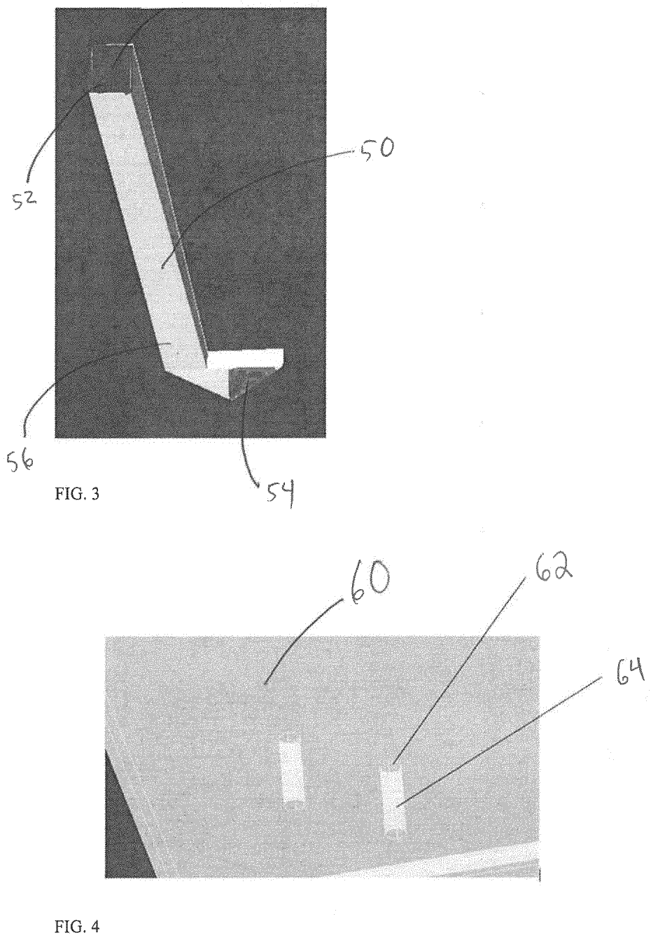

FIG. 3 illustrates a light guide 50 according to an embodiment. In this embodiment, the light guide is a light pipe, though it should be understood that other embodiments may have other configurations. The illustrated light guide includes an entry aperture 52 and an exit aperture 54. The light guide also includes exterior surfaces 56. In some embodiments, the exterior surfaces are coated with a reflective material (e.g., greater than 92% reflective, greater than 95% reflective, etc.). It is possible that the entry aperture 52 and the exit aperture 54 has any couture shape and also may d\form any surface shape which n\may be curved and not planar. The entry aperture 52 and the exit aperture 54 may ai a different direction

FIG. 4 illustrates a light guide 60 according to an embodiment. As shown, the light guide includes holes 62 that extend from a top surface of the light guide to a bottom surface of the light guide. An inner surface 64 of the holes may be coated with a reflective material. For example, the inner surfaces may be coated with a diffuse reflective material. In some cases, the reflective material is a silicone material though it should be understood that other reflective materials may be used. The light that propagates inside the light guide can interact with the hole and is scattered into multiple directions and continues to propagate inside the light guide. The light guide in this embodiment may be used in connection with LED(s) that emit light into a side of the light guide or into a bottom of the light guide.

Holes 62 may have any suitable shape. In some embodiments, the holes have a circular cross-section and/or have a cylindrical shape.

In the above-described embodiments, it should be understood that any suitable LED and/or array of LEDs may be used.

In the above-described embodiments, the light guide(s) may have any suitable configuration as known in the art. In some cases, the light guide may have a planar shape (e.g., rectangular, square); in other cases, the light guide may have a tube (or pipe) shape. In general, the length and/or width of the light guide (e.g., when in a planar shape) may be larger than the thickness (e.g., cross-section) of the light guide. The dimensions of the light guide may be dictated by the application in which the light guide is used.

In the above-described embodiments, the light guide(s) may be made of any suitable material. In some cases, as noted above, it may be preferred for the light guide to comprise a silicone material. In some embodiments, the light guide is formed primarily (e.g., greater than 50% by weight, greater than 70% by weight, greater than 90% by weight) or essentially entirely of silicone. In some embodiments, the CSM may consist essentially of a silicone material. In some embodiments, additives (e.g., particles) may be added to the silicone material to impart desirable properties (e.g., reflectivity).

In some embodiments, the silicone may be highly reflective. In some such embodiments, the silicone may have a white reflective color (e.g., white silicone). Suitable silicones include CI-2001 (Dow Corning) and MS-2002 (Dow Corning). In some embodiments, the reflective silicone may have a reflectance of at least 93% for light (e.g., in the visible region). In some cases, the reflective silicone may have a reflectance of at least 95% for light (e.g., in the visible region).

In some embodiments, the light guide may be molded and the silicone material may be a potting material. In such cases when the light guide is molded, the mold surface may be designed to include features that form the coupling pattern (e.g., out-coupling pattern, in-coupling pattern) on the light guide. In certain embodiments, the mold may include other features that form other corresponding features on the light guide (e.g., the air cavity, recesses for the PCB.

In some embodiments, the light guide, itself, or an additional layer on the light guide may include phosphor material. The phosphor material may be used to convert the wavelength of light emitted by the LED(s) into the light guide. For example, the phosphor material, may be in the form of particles which are incorporated into silicone (e.g., the silicone material of the light guide and/or the silicone material of an additional layer formed on the light guide).

In the embodiments described above, surfaces of the components such as the light guide and/or PCB may be coated with material. For example, the material may be reflective. In some cases, the coating may be highly reflective (e.g., white silicone material); and, in other cases, the coating may have a lower reflectivity (e.g., black silicone material).

It should be appreciated that the embodiments described herein may be implemented in any of numerous ways. Examples of specific implementations are provided herein for illustrative purposes only. It should be appreciated that these embodiments and the features/capabilities provided may be used individually, all together, or in any combination of two or more, as aspects of the technology described herein are not limited in this respect.

### Example 1

Different systems including LEDs and light guides were constructed and evaluated for performance.

System 1 included an array of 25 LEDs (Model SBT-90) mounted on a PCB and configured to emit light into a side of a light guide (“side in-coupling”) as shown schematically in FIG. 1. The light guide was plate-shaped. The LEDs were positioned in an air cavity within the light guide. An out-coupling structure was formed on a bottom surface of the light guide. The System included a bottom diffuse reflector. The edges of the light guide and PCB were coated with a white diffuse reflector.

System 2 was similar to System 1 except that it included an array of 25 LEDs (Model SST-90).

System 3 included an array of 25 LEDs (Model SBT-90) mounted on a PCB and embedded in a bottom portion of the light guide as shown in FIG. 2. The LEDs emit light into a bottom surface of the light guide (“bottom in-coupling”). The system included a bottom diffuse reflector and a top diffuse reflector. A prismatic groove was positioned above the array of LEDs. The edges of the light guide and PCB were coated with a white diffuse reflector.

System 4 was similar to System 1 except that it included an array of 25 LEDs (Model SST-90).

The table below shows performance metrics of the systems.

| | Single LED | Total Luminous | Light guide |
|---|---|---|---|
| System | emittance | flux | efficacy |
| 1 | 2000 | 27156 | 54% |
| 2 | 1000 | 16288 | 65% |
| 3 | 2000 | 21383 | 43% |
| 4 | 1000 | 10916 | 44% |

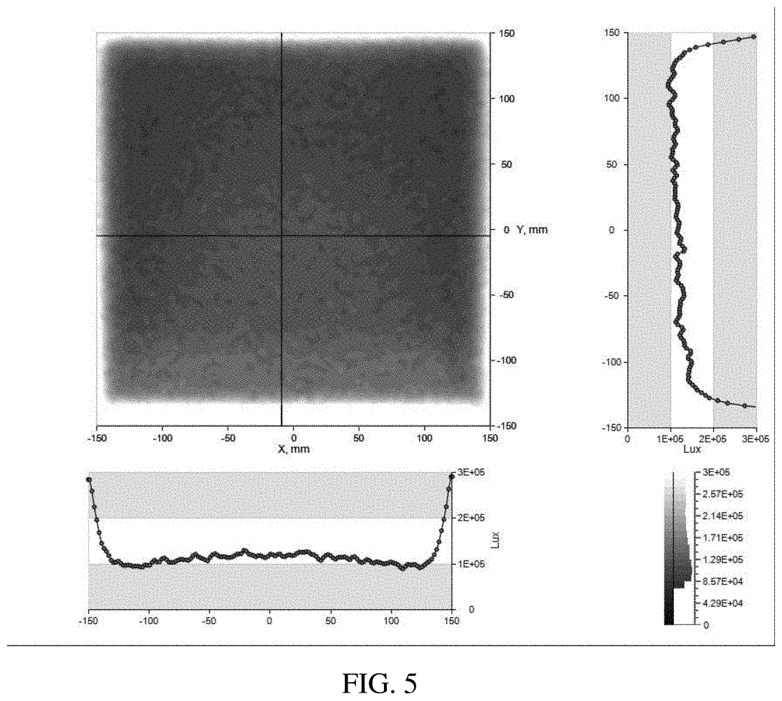

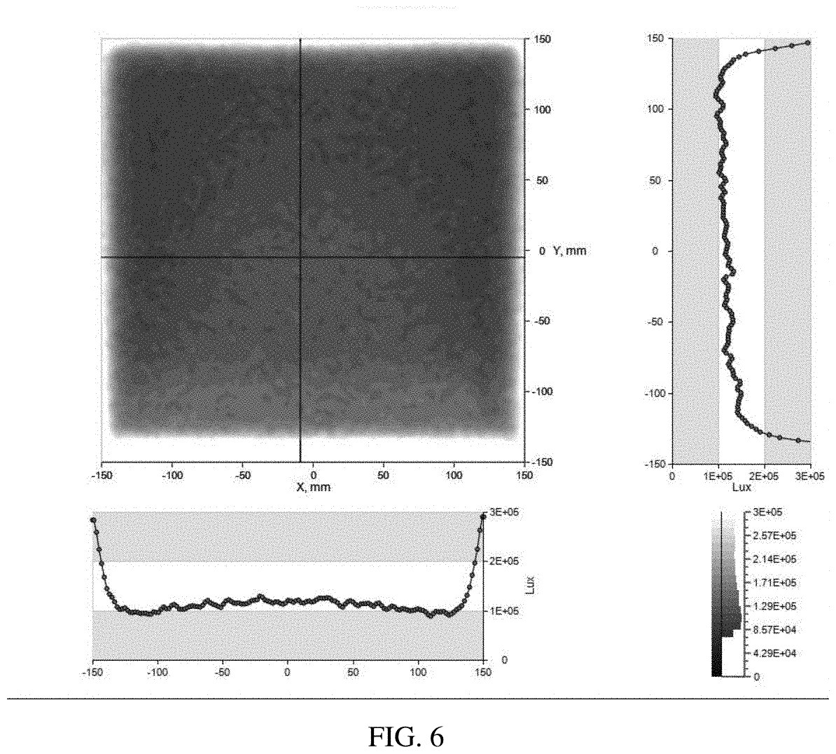

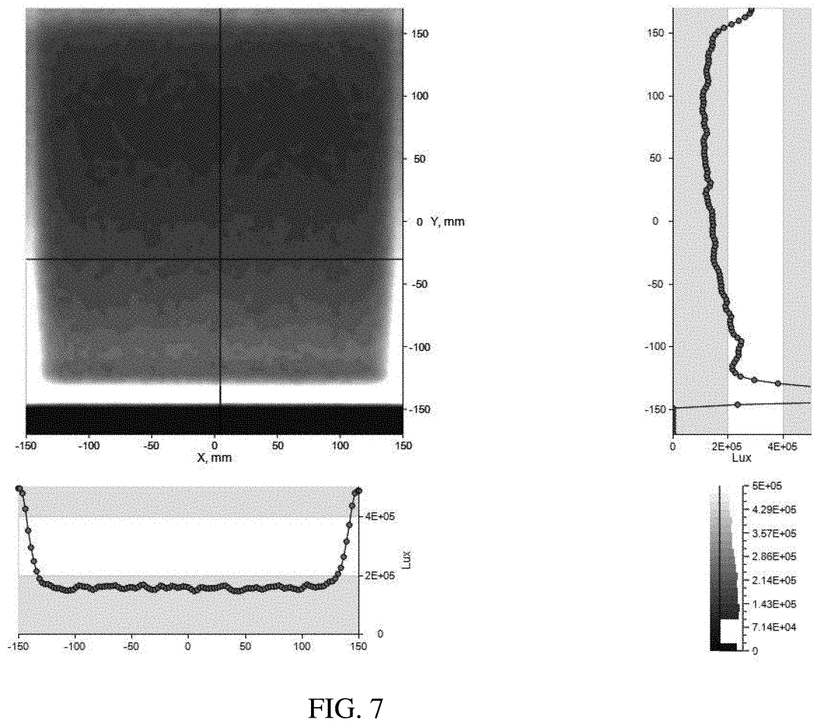

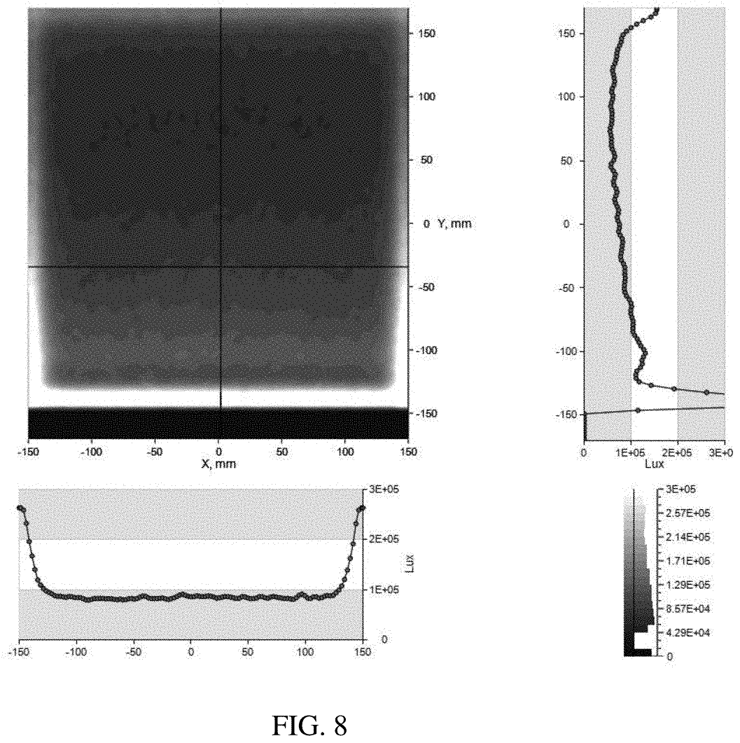

FIG. 5 shows the light intensity distribution on a top surface of the light guide for System 1. FIG. 6 shows the light intensity distribution on a top surface of the light guide for System 2. FIG. 7 shows the light intensity distribution on a top surface of the light guide for System 3. FIG. 8 shows the light intensity distribution on a top surface of the light guide for System 4.

All of the Systems had good performance. System 2 had the best light guide efficacy. All of the Systems had similar light intensity distributions at a top surface of the light guide.

### Example 2

Different systems including LEDs and light guides were constructed and evaluated for simulated performance.

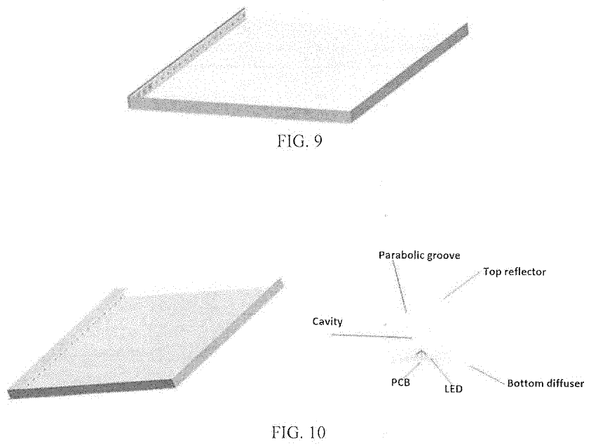

Simulated Systems 1A-1F included an array of 20 white LEDs (Model SBT-90 with an illumination area of 3×3 mm²) mounted on a PCB and configured to emit light into a side edge of a light guide (“side in-coupling”) as shown schematically in FIG. 9. The light guide was plate-shaped (300 mm×300 m×15 mm) and comprised a silicone material. The Systems included a bottom diffuse reflector (reflectivity 98%). In some cases (Systems 1A, 1C, 1E), the edges of the light guide were coated with a white diffuse material (reflectivity 98%); and, in other cases (Systems 1B, 1D, 1F), the edges of the light guide were coated with aluminum (reflectivity 80%). An out-coupling structure was formed on a bottom surface of the light guide In some cases (Systems 1E, 1F), the out-coupling structure comprised hemispheres with a height of 16 microns and a base diameter of 100 microns; in some cases (Systems 1A, 1B), the out-coupling structure comprised prisms having a first design; and, in some cases (Systems 1C, 1D), the out-coupling structure comprised prisms having a second design.

Simulated Systems 2A-2C included an array of 20 white LEDs (Model SBT-90 with an illumination area of 3×3 mm²) mounted on a PCB and configured to emit light into a bottom of a light guide (“bottom in-coupling”) as shown schematically in FIG. 10. The array of LEDs was positioned in a cavity on the bottom of the light guide near one of the side edges. The light guide was plate-shaped (300 mm×300 m×15 mm) and comprised a silicone material. The Systems included a bottom diffuse reflector (reflectivity 98%). In some cases (Systems 2A, 2C), the edges of the light guide were coated with a white diffuse material; and, in another case (Systems 2B), the edges of the light guide were coated with aluminum (reflectivity 80%). An out-coupling structure was formed on a bottom surface of the light guide In some cases (System 2A, 2B), the out-coupling structure comprised hemispheres with a height of 16 microns and a base diameter of 100 microns; and, in another case (Systems 2B), the out-coupling structure comprised prisms (similar to the second design noted above).

The table below shows the results of the simulations.

| Simulated | | | Out-coupling | Light guide |
|---|---|---|---|---|
| System | Coating | | Structure | efficacy |
| 1A | White | (98%) | Prism 1 | 51% |
| 1B | Al | (80%) | Prism 1 | 47% |
| 1C | White | (98%) | Prism 2 | 53% |
| 1D | Al | (80%) | Prism 2 | 49% |
| 1E | White | (98%) | Hemispheres | 52% |
| 1F | Al | (80%) | Hemispheres | 50% |
| 2A | White | (98%) | Hemispheres | 42% |
| 2B | Al | (80%) | Hemispheres | 30% |
| 2C | White | (98%) | Prism 1 | 45% |

All of the Simulated Systems had good performance. The Systems including light guides having edges coated with a white diffuse material (reflectivity 98%) performed better than the Systems having edges coated white aluminum (reflectivity 80%).

What is claimed is:

1. A system comprising:
a light-emitting diode; and
a light guide configured to receive light emitted by the light-emitting diode, wherein the light propagates inside the light guide,
the light guide comprising at least one hole that extends from a top surface of the light guide to a bottom surface of the light guide,
the hole being defined by an inner surface, wherein the inner surface is coated with a reflective material.

2. The system of claim 1, wherein the light guide comprises a plurality of holes that extend from a top surface of the light guide to a bottom surface of the light guide, wherein the holes are respectively defined by an inner surface, wherein the inner surfaces are coated with a reflective material.

3. The system of claim 1, wherein the inner surfaces are coated with a diffuse reflective material.

4. The system of claim 1, wherein the diffuse reflective material comprises silicone material.

5. The system of claim 1. wherein the light that propagates inside the light guide interacts with the hole and is scattered into multiple directions and continues to propagate inside the light guide.

6. The system of claim 1, wherein the light-emitting diode emits light into a side of the light guide.

7. The system of claim 1, wherein the light-emitting diode emits light into a bottom of the light guide.

8. The system of any of claim 1, further comprising a plurality of light-emitting diodes that emit light that is received by the light guide.

9. The system of any of claim 1, wherein the holes have a circular cross-section.

10. The system of any of claim 1, wherein the holes have a cylindrical shape.

11. The system of any of claim 1, wherein the light guide comprises silicone.

12. The system of any of claim 1, wherein the light guide is a light pipe.

13. A system comprising:
a light-emitting diode configured to emit light; and
a light guide configured to receive the light emitted by the light-emitting diode through an entrance aperture, wherein the light propagates inside the light guide and is emitted through an exit aperture,
wherein the light guide has a length that extends from the entrance aperture to the exit aperture and a width that is perpendicular to the length and defines a cross-section of the light guide,
wherein exterior surfaces of the light guide except for the entrance aperture and the exit aperture are coated with a reflective material that reflects greater than 92% of the transmitted light.

14. The system of claim 13, wherein the light guide is a light pipe.

15. The system of claim 13, wherein the reflective material reflects greater than 95% of the transmitted light.

16. The system of claim 13, wherein the reflective material is opaque.

17. The system of claim 13, wherein the light propagates from the entrance aperture to the exit aperture with substantially no leakage.

18. The system of claim 13, wherein the light guide comprises a silicone material.

19. The system of claim 13, wherein the light guide comprises a continuous geometric shape.

20. A system comprising:
a light-emitting diode configured to emit light; and
a light guide configured to receive the light emitted by the light-emitting diode, wherein the light propagates inside the light guide,
wherein the light guide is a molded structure comprising silicone material and includes a light coupling pattern on an exterior surface of the light guide.

21-37. (canceled)
